(19) United States
(12) Patent Application Publication
(10) Pub. No.: US 2025/0129917 A1
(43) Pub. Date: Apr. 24, 2025

(54) OPTICAL COMPONENT MOUNTING PACKAGE AND OPTICAL APPARATUS

(71) Applicant: KYOCERA Corporation, Kyoto-shi, Kyoto (JP)

(72) Inventors: Kaichiro NAKASHIMA, Saga-shi (JP); Masahiko TANIGUCHI, Kirishima-shi (JP); Yuuki HARUTA, Kirishima-shi (JP); Junko YOSHIHARA, Kirishima-shi (JP)

(73) Assignee: KYOCERA Corporation, Kyoto-shi, Kyoto (JP)

(21) Appl. No.: 18/695,677

(22) PCT Filed: Sep. 26, 2022
(86) PCT No.: PCT/JP2022/035641

§ 371 Date: Mar. 26, 2024

(30) Foreign Application Priority Data
Sep. 27, 2021 (JP) 2021-156297

(51) Int. Cl. F21V 17/10; F21V 31/00; F21Y 115/10; F21Y 115/30; H10H 20/85

(52) U.S. Cl. CPC F21V 17/101; F21V 31/005; H10H 20/8506; F21Y 2115/10; F21Y 2115/30

(57) ABSTRACT

An optical component mounting package includes a mount on which an optical component is to be mounted, a wall including an opening, a light-transmitting member configured to cover the opening, and a joint material configured to join the light-transmitting member to the wall. The light-transmitting member includes a first surface facing the opening or disposed inside the opening, a second surface disposed opposite the first surface, and a side surface disposed between the first surface and the second surface. The joint material is a low-melting glass and is in contact with the wall, the side surface, and the second surface.

### TECHNICAL FIELD

The present disclosure relates to an optical component mounting package and an optical apparatus.

### BACKGROUND OF INVENTION

Japanese Unexamined Patent Application Publication No. 2015-052629 discloses an optical component mounting package that includes a mount on which an optical component is to be mounted, a wall including an opening, and a light-transmitting member configured to close the opening. The light-transmitting member is joined to the wall, with a low-melting glass and a joint material made of resin therebetween.

### SUMMARY

### Solution to Problem

In the present disclosure, an optical component mounting package includes a mount on which an optical component is to be mounted, a wall including an opening, a light-transmitting member configured to cover the opening, and a joint material configured to join the light-transmitting member to the wall. The light-transmitting member includes a first surface facing the opening or disposed inside the opening, a second surface disposed opposite the first surface, and a side surface disposed between the first surface and the second surface. The joint material is a low-melting glass and is in contact with the wall, the side surface, and the second surface.

In the present disclosure, an optical apparatus includes the optical component mounting package, and an optical component mounted in the optical component mounting package.

### BRIEF DESCRIPTION OF THE DRAWINGS

FIG. 1 is an exploded perspective view of an optical component mounting package and an optical apparatus according to an embodiment of the present disclosure.

FIG. 2A is a front view of the optical component mounting package according to the embodiment.

FIG. 2B is a plan view of the optical component mounting package according to the embodiment.

FIG. 2C is a side view of the optical component mounting package according to the embodiment.

FIG. 3A is a cross-sectional view illustrating the vicinity of an opening of the optical component mounting package according to the embodiment.

FIG. 3B is an enlarged view illustrating a joint region Q1 of a light-transmitting member of the optical component mounting package according to the embodiment.

FIG. 4A is a cross-sectional view illustrating the vicinity of the opening of the optical component mounting package according to Variation 1.

FIG. 4B is a cross-sectional view illustrating the vicinity of the opening of the optical component mounting package according to Variation 2.

FIG. 5 is a cross-sectional view illustrating the vicinity of the opening of the optical component mounting package according to Variation 3.

FIG. 6A is a front view illustrating the vicinity of the opening of the optical component mounting package according to Variation 4.

FIG. 6B is a cross-sectional view illustrating the vicinity of the opening of the optical component mounting package according to Variation 4.

FIG. 7 is an explanatory diagram illustrating an example of how the light-transmitting member is joined in Variation 4.

FIG. 8A is a front view illustrating the light-transmitting member of the optical component mounting package according to Variation 5.

FIG. 8B is a cross-sectional view illustrating the vicinity of the opening of the optical component mounting package according to Variation 5.

FIG. 9A is a front view illustrating the light-transmitting member of the optical component mounting package according to Variation 6.

FIG. 9B is a cross-sectional view illustrating the vicinity of the opening of the optical component mounting package according to Variation 7.

FIG. 10A is a cross-sectional view illustrating the vicinity of the opening of the optical component mounting package according to Variation 8.

FIG. 10B is a cross-sectional view illustrating the vicinity of the opening of the optical component mounting package according to Variation 9.

### DESCRIPTION OF EMBODIMENTS

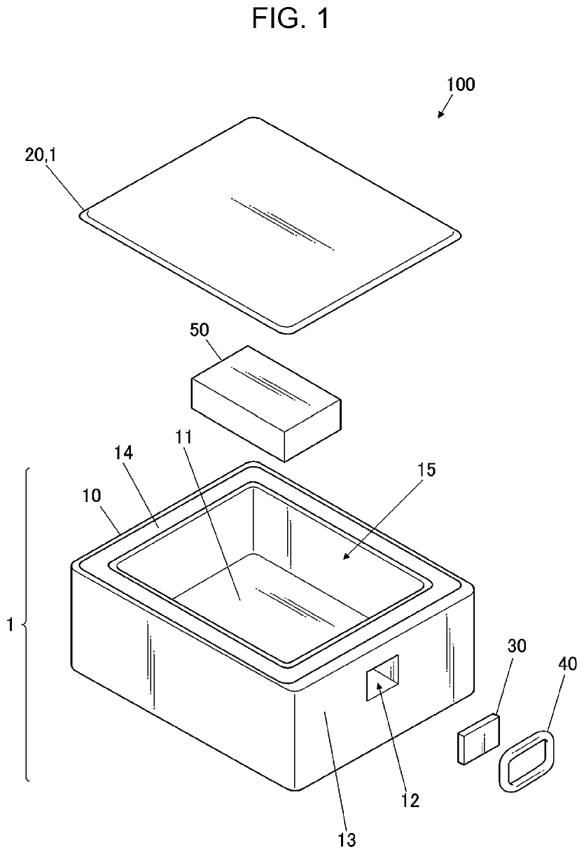

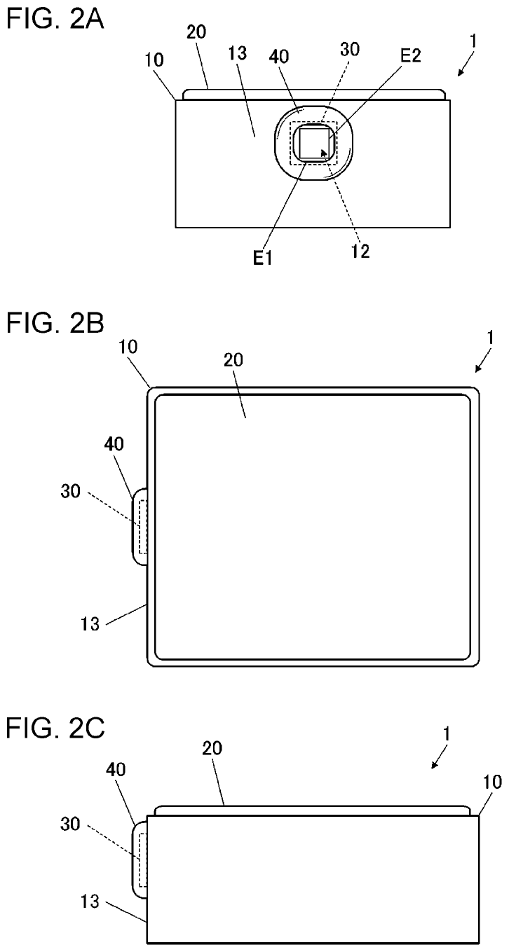

Embodiments of the present disclosure will now be described in detail with reference to the drawings. FIG. 1 is an exploded perspective view of an optical component mounting package and an optical apparatus according to an embodiment of the present disclosure. FIG. 2A to FIG. 2C are a front view, a plan view, and a side view of the optical component mounting package according to the embodiment.

In the present embodiment, an optical component mounting package 1 includes a mount 11 on which an optical component 50 is to be mounted, a wall 13 including an opening 12, a light-transmitting member 30 configured to close the opening 12, and a joint material 40 configured to join the light-transmitting member 30 to the wall 13. The opening 12 may be a through-hole in the wall 13. The opening 12 may be disposed to face the optical component 50 mounted on the mount 11. The opening 12 can allow light to enter and exit the optical component mounting package 1.

As illustrated in FIG. 1, the optical component mounting package 1 may include a base body 10, and the base body 10 may include the mount 11 and the wall 13. That is, a component including the mount 11 and a component including the wall 13 may be integrated. Alternatively, a component including the mount 11 and a component including the wall 13 may be separate bodies that are joined together.

The base body 10 may include a recessed accommodating portion 15, and the mount 11 may be disposed inside the accommodating portion 15. The optical component mounting package 1 may further include a lid 20 configured to hermetically close the accommodating portion 15. The base body 10 may include a joint surface 14 around the accommodating portion 15 to which the lid 20 is joined. The lid 20 may be joined to the joint surface 14 by seam welding or the like.

The base body 10 may include an insulating portion made of an insulating material, and a conductor portion disposed inside and on the surface of the insulating portion. Power, signals, or both may be transferred between the outside and the inside of the base body 10 through the conductor portion. The insulating portion of the base body 10 may be made of a ceramic material, such as sintered aluminum oxide (alumina ceramics), sintered aluminum nitride, sintered mullite, or sintered glass ceramics.

The wall 13 may be made of a material same as, and/or similar to, that of the base body 10. When the wall 13 is made of a ceramic material, the strength of the base body 10 can be improved. When the component including the mount 11 and the component including the wall 13 are separate bodies, the wall 13 may be made of metal.

The light-transmitting member 30 has light-transmitting characteristics and is made of a material that can withstand the temperature at which the joint material 40 melts. The light-transmitting member 30 may be made of glass. The light-transmitting member 30 may be a plate-like member, and is joined to the wall 13 in such a way as to close the opening 12. The light-transmitting member 30 does not need to “close (or cover)” the opening 12 in a strict sense. For example, 70% or more of the opening 12 is simply required to overlap the light-transmitting member 30 in plan view. The light-transmitting member 30 can allow light to enter and exit the optical component mounting package 1.

The joint material 40 may be a low-melting glass. With low-melting glass, the light-transmitting member 30 can be joined to the base body 10 at a temperature lower than that at which a known joint material of glass is used. This can not only improve reliability of the optical component mounting package 1, but can also facilitate maintenance of facilities required for the joining. Low-melting glass refers to a glass that softens and deforms at a lower temperature than the light-transmitting member 30. Specifically, low-melting glass is an amorphous or crystalline glass that softens, deforms, and flows at a temperature of 200° C. to 950° C. Crystalline glass refers to a composite of glass, which is amorphous, and a crystalline material. Examples of low-melting glass that can be used include borosilicate glass, barium borosilicate glass, zinc borate glass, barium borate glass, high silicate glass, aluminophosphate glass, phosphate glass, zinc phosphate glass, alkali glass, bismuth silicate glass, bismuth borosilicate glass, bismuth zinc borate glass, lead borosilicate glass, lead borate glass, potash lead glass, and crystalline lead glass.

Low-melting glass has a higher surface tension in a fluid state than solder or resin adhesives. To reduce the surface area, low-melting glass acts strongly to become closer to spherical. Low-melting glass has less strict constraints on objects to be joined than solder. A constraint that arises when the joint material 40 is of solder and the wall 13 is of an insulating material is that the joint portion of the wall 13 requires metallization and plating. Low-melting glass has higher airtightness than resin adhesives. With low-melting glass, airtightness of the optical component mounting package 1 can be improved. Additionally, low-melting glass has higher heat resisting temperature than resin adhesives. With this high heat resisting temperature, thermal constraints can be reduced which arise when the optical component 50 is to be mounted in the optical component mounting package 1 or the optical component mounting package 1 (optical apparatus 100) having the optical component 50 mounted therein is to be mounted on a module substrate. This can increase the degree of freedom in selecting the mounting method.

### <Details of Joint Area>

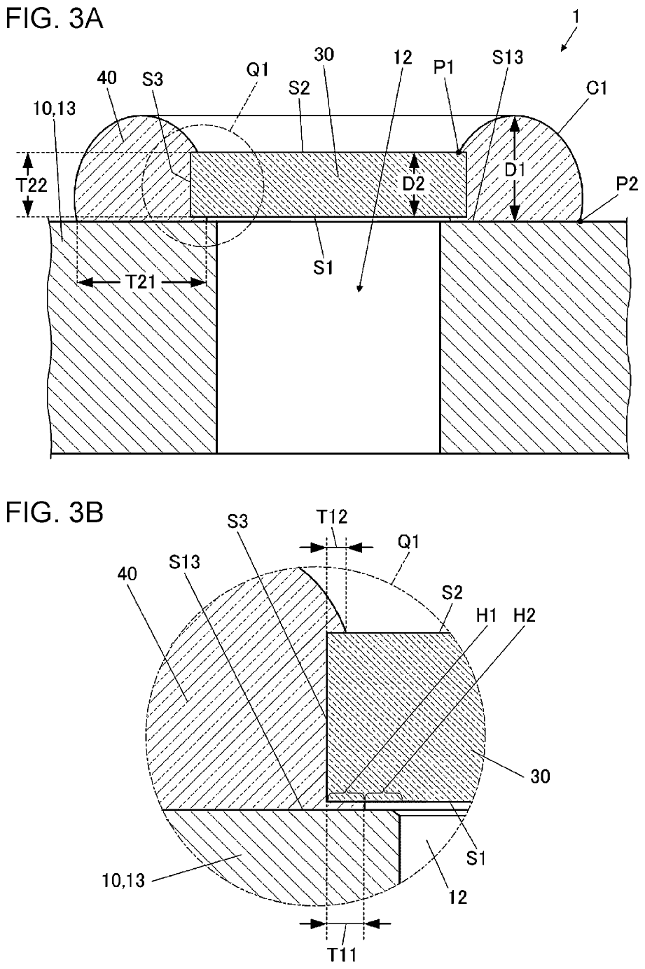

FIG. 3A is a cross-sectional view illustrating the vicinity of the opening of the optical component mounting package according to the embodiment. FIG. 3B is an enlarged view illustrating a joint region Q1 of the light-transmitting member of the optical component mounting package according to the embodiment.

As illustrated in FIG. 3A, the light-transmitting member 30 includes a first surface S1 facing the opening 12, a second surface S2 opposite the first surface S1, and a side surface S3 disposed between the first surface S1 and the second surface S2. The joint material 40 is in contact with the wall 13, the side surface S3 of the light-transmitting member 30, and the second surface S2 of the light-transmitting member 30. Here, being in contact may mean adhering. A portion of the joint material 40 in contact with the wall 13, a portion of the joint material 40 in contact with the side surface S3, and a portion of the joint material 40 in contact with the second surface S2 may be connected to each other. The joint material 40 may be in contact with an edge of the second surface S2. The joint material 40 may be in contact with the side surface S3 in a region from an end portion of the side surface S3 adjacent to the first surface S1 to an end portion of the side surface S3 adjacent to the second surface S2. In this region from the end portion of the side surface S3 adjacent to the first surface S1 to the end portion of the side surface S3 adjacent to the second surface S2, the joint material 40 may be partially spaced apart from the side surface S3.

When the joint material 40 is in contact with the side surface S3 and the second surface S2 of the light-transmitting member 30, the joint material 40 presses the light-transmitting member 30 in a direction from the second surface S2 toward the first surface S1. This provides a high joint strength between the wall 13 and the light-transmitting member 30. The joint material 40 in contact with the second surface S2 serves to protect the light-transmitting member 30 from external obstacles. This can reduce damage to the light-transmitting member 30, and thus can improve the strength of a light-transmitting part of the optical component mounting package 1. Also, the joint material 40, which is low-melting glass, acts strongly to become spherical before it hardens. Therefore, even when the joint material 40 is on the second surface S2, the joint material 40 is less likely to spread over a large area of the second surface S2. The area of an effective region of the light-transmitting member 30 can thus be easily secured while the joint material 40 is on the second surface S2. The effective region refers to a region through which light can normally pass.

As viewed from the front (i.e., in a direction perpendicular to the first surface), the structure where the joint material 40 is in contact with the wall 13, the side surface S3, and the second surface S2 may be present along the entire periphery of the light-transmitting member 30, or may be present along the entire periphery of the light-transmitting member 30 except some region. When the structure described above is present along the entire periphery of the light-transmitting member 30, the effects described above can be achieved in the entire region along the edge, and the strength of the light-transmitting part can be further improved.

As illustrated in FIG. 3A, a thickness D1 of the joint material 40 may be greater than a thickness D2 of the light-transmitting member 30. With this configuration, the joint material 40 protrudes above the second surface S2 of the light-transmitting member 30 in a thickness direction. Here, the term “thickness” refers to a thickness in the direction perpendicular to the first surface S1. If the thickness varies, “thickness” here means the thickness of a region having the largest thickness. The joint material 40 may protrude above the second surface S2 regardless of the thicknesses D1 and D2. The direction of protrusion is the direction perpendicular to the first surface S1. The protruding portion of the joint material 40 can protect the light-transmitting member 30 from external obstacles. This can further improve the strength of the light-transmitting part of the optical component mounting package 1.

As illustrated in FIG. 3B, the joint material 40 may further be in contact with the first surface S1 of the light-transmitting member 30. This configuration increases the area of contact between the joint material 40 and the light-transmitting member 30 and can further improve the joint strength between the light-transmitting member 30 and the wall 13. The joint material 40, which is low-melting glass, acts strongly to become spherical before it hardens. Therefore, even when the joint material 40 is on the first surface S1, the joint material 40 is less likely to spread over a large area of the first surface S1. The area of the effective region of the light-transmitting member 30 can thus be easily secured while the joint material 40 is on the first surface S1.

As illustrated in FIG. 3B, the wall 13 may include a third surface S13 surrounding the opening 12 and facing the first surface S1 of the light-transmitting member 30. The joint material 40 may be disposed between the first surface S1 of the light-transmitting member 30 and the third surface S13 of the wall 13. In the space between the first surface S1 and the third surface S13, the joint material 40 may be disposed in a first range H1 farther from the opening 12 and a gap may be disposed in a second range H2 closer to the opening 12. This configuration can increase the area of contact between the joint material 40 and the light-transmitting member 30 while reducing the overlap of the joint material 40 on the second surface S2 with the opening 12, and improve the joint strength between the wall 13 and the light-transmitting member 30. Even when stress produced between the wall 13 and the light-transmitting member 30 by the gap in the second range H2 is applied to an end of the inner periphery of the joint material 40 between the first surface S1 and the second surface S2, the concentration of stress can be relieved by increasing the area where stress is applied. The strength and durability of the light-transmitting part of the optical component mounting package 1 can thus be improved.

As illustrated in FIG. 3B, in the cross-section perpendicular to the first surface S1, a length T11 of a contact between the joint material 40 and the first surface S1 may be greater than a length T12 of a contact between the joint material 40 and the second surface S2. This configuration can further improve airtightness of the opening 12 provided by the light-transmitting member 30 and the joint material 40. Here, the term “length” refers to an apparent length that ignores surface roughness and fine irregularities.

As illustrated in FIG. 3A, in the cross-section perpendicular to the first surface S1, a length T21 of a contact between the joint material 40 and the wall 13 may be greater than a length T22 of a contact between the joint material 40 and the side surface S3 of the light-transmitting member 30. This configuration provides high flatness of the joint material 40 and reduces damage to the joint material 40 caused, for example, by vibration, stress, or collision with objects. The strength and durability of the light-transmitting part of the optical component mounting package 1 can thus be improved. Here, the term “length” refers to an apparent length that ignores surface roughness and fine irregularities.

As illustrated in FIG. 3A, in the cross-section perpendicular to the first surface S1, the contour of the joint material 40 may include an outward curve C1. Curve refers to a smoothly bending line. The curve C1 may be in the shape of a circular arc. Examples of the circular arc include not only an arc of a perfect circle, but also an arc of an elongated circle, and an arc of an ellipse. More specifically, a part of the contour of the joint material 40, extending from an end point P1 of the contact between the joint material 40 and the second surface S2 to an end point P2 of the contact between the joint material 40 and the wall 13, may be the outward curve C1. With the outward curve C1, damage to the joint material 40 caused, for example, by vibration, stress, or collision with objects can be reduced, and the strength and durability of the light-transmitting part of the optical component mounting package 1 can be improved.

As illustrated in FIG. 2A, the joint material 40 may have an annular shape along the edge of the light-transmitting member 30, as viewed from the front (i.e., in the direction perpendicular to the first surface S1). With this annular shape, the light-transmitting member 30 can be protected from external obstacles, because the joint material 40 is less discontinuous in shape. This can improve the strength and durability of the light-transmitting part of the optical component mounting package 1. Since the joint material 40 is continuous throughout the circumference along the edge of the light-transmitting member 30, the airtightness of the opening 12 can be further improved.

As illustrated in FIG. 2A, when viewed through from the front, an inner peripheral edge E1 of the joint material 40 may overlap an edge E2 of the opening 12, or may be disposed outside the edge E2 of the opening 12. The inner peripheral edge E1 of the joint material 40 may partially overlap the edge E2 of the opening 12, and the remaining part of the inner peripheral edge E1 of the joint material 40 may be disposed outside the edge E2 of the opening 12. This configuration can reduce the possibility that the joint material 40 will cover the opening 12. The effective area of the opening 12 through which light passes can thus be maintained.

As illustrated in FIG. 1, the light-transmitting member 30 may be jointed to the outer surface (third surface S13, see FIG. 3A) of the wall 13. That is, the second surface S2 of the light-transmitting member 30 (FIG. 3A) may be disposed opposite the mount 11 with respect to the opening 12. This configuration can reduce the possibility that the light-transmitting member 30 will protrude toward the mount 11, and thus can make the mount 11 and the optical component mounting package 1 compact. Additionally, this configuration can facilitate the process of joining the light-transmitting member 30.

In the present embodiment, the configuration of one or more of Variations 1 to 7, described below, may be added to the optical component mounting package 1.

### (Variations 1 and 2)

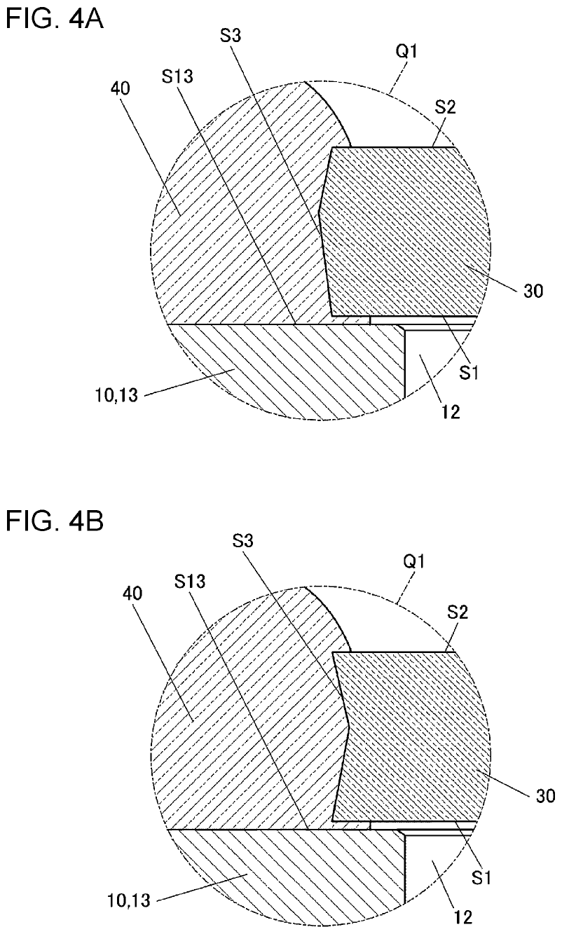

FIG. 4A is a cross-sectional view illustrating the vicinity of the opening of the optical component mounting package according to Variation 1. FIG. 4B is a cross-sectional view illustrating the vicinity of the opening of the optical component mounting package according to Variation 2. As illustrated in FIG. 4A, in the cross-section perpendicular to the first surface S1, the side surface S3 of the light-transmitting member 30 may have a convex shape. As illustrated in FIG. 4B, in the cross-section perpendicular to the first surface S1, the side surface S3 of the light-transmitting member 30 may have a concave shape. The entire side surface S3 may form a convex shape, or a part of the side surface S3 may form a convex shape. The entire side surface S3 may form a concave shape, or a part of the side surface S3 may form a concave shape. This configuration enables an anchoring action of the side surface S3 on the joint material 40, and can ensure firm joint between the light-transmitting member 30 and the wall 13. The strength and durability of the light-transmitting part of the optical component mounting package 1 can thus be improved.

### (Variation 3)

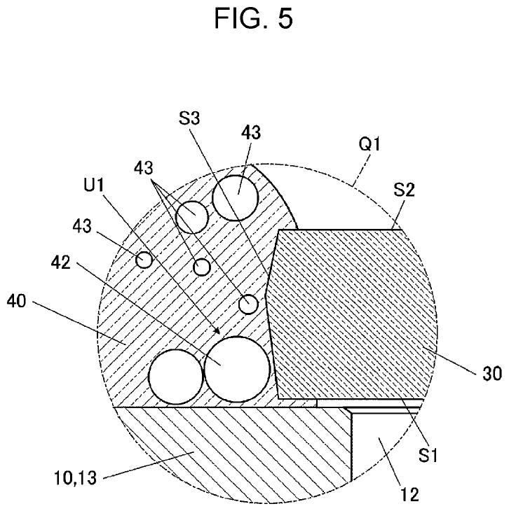

FIG. 5 is a cross-sectional view illustrating the vicinity of the opening of the optical component mounting package according to Variation 3. As illustrated, the joint material 40 may contain bubbles 42 in a corner U1 between the side surface S3 of the light-transmitting member 30 and the wall 13. When stress is produced between the wall 13 and the light-transmitting member 30, the bubbles 42 in the corner U1 can reduce concentration of the stress in the corner U1. This can reduce the possibility that stress will break the joint material 40, and thus can further improve the strength and durability of the light-transmitting part of the optical component mounting package 1.

For example, in the cross-section illustrated in FIG. 5, the corner U1 is a region surrounded by a quadrangle that includes the light-transmitting member 30 and the outer surface of the wall 13 as sides and has a length half the thickness of the light-transmitting member 30 on a side. As illustrated in FIG. 5, the joint material 40 may contain bubbles 43 in a region outside the corner U1. The bubbles 42 in the corner U1 may be greater than the bubbles 43 in the region outside the corner U1. In the cross-section of the joint material 40 illustrated in FIG. 5, the density of the bubbles 42 in the corner U1 may be higher than the density of the bubbles 43 in the region outside the corner U1. This can distribute stress in the corner U1 where stress tends to concentrate while increasing the density of the joint material 40. The possibility that stress will break the joint material 40 can thus be reduced, and the strength and durability of the light-transmitting part of the optical component mounting package 1 can be further improved.

### (Variation 4)

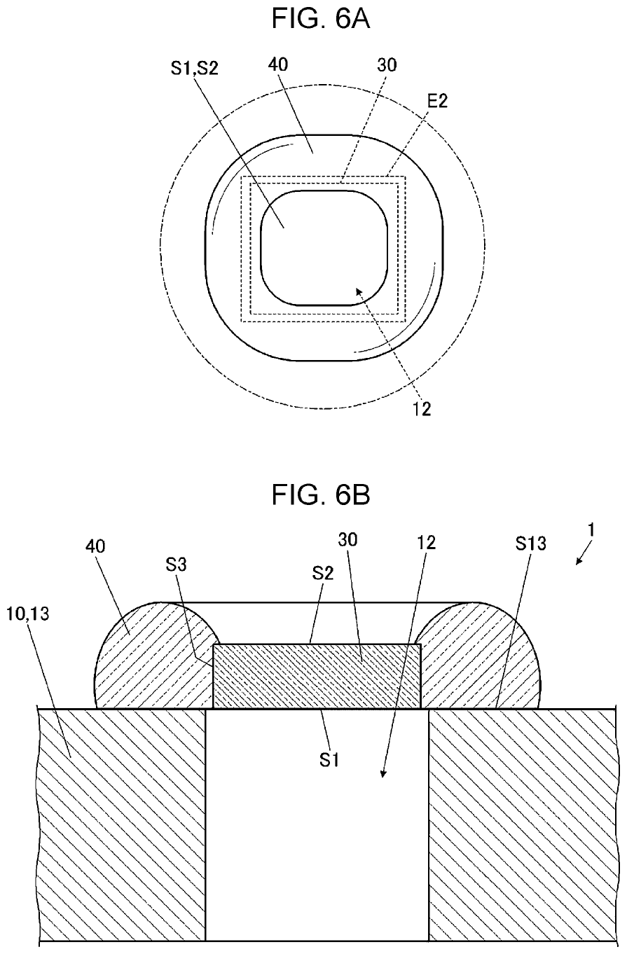

FIG. 6A and FIG. 6B are a front view and a cross-sectional view, respectively, each illustrating the vicinity of the opening of the optical component mounting package according to Variation 4. As illustrated in FIG. 6A and FIG. 6B, when viewed through in a direction perpendicular to the first surface S1, the entire contour of the light-transmitting member 30 may be disposed inside the edge E2 of the opening 12. This configuration can reduce the occurrence of stress between the wall 13 and the light-transmitting member 30, and thus can reduce the possibility that the light-transmitting member 30 will be damaged. The strength and durability of the light-transmitting part of the optical component mounting package 1 can thus be further improved. By making the light-transmitting member 30 smaller, the size of the optical component mounting package 1 can be reduced. Note that viewing through refers to viewing an object while virtually excluding objects in front of the object being viewed through. If the objects in front of the object being viewed through have a lens effect that distorts an image, the distorted image differs from an image of the object being viewed through.

In Variation 4, as illustrated in FIG. 6B, the first surface S1 of the light-transmitting member 30 may be flush with the outer surface (third surface S13) of the wall 13. Alternatively, the first surface S1 of the light-transmitting member 30 may be disposed either outside or inside the opening 12. In other words, the first surface S1 of the light-transmitting member 30 may be disposed either outside or inside (close to the mount 11) the position where it is flush with the outer surface (third surface S13) of the wall 13.

In Variation 4, the joint material 40 does not necessarily need to be disposed on the first surface S1 of the light-transmitting member 30, but may be disposed on the first surface S1.

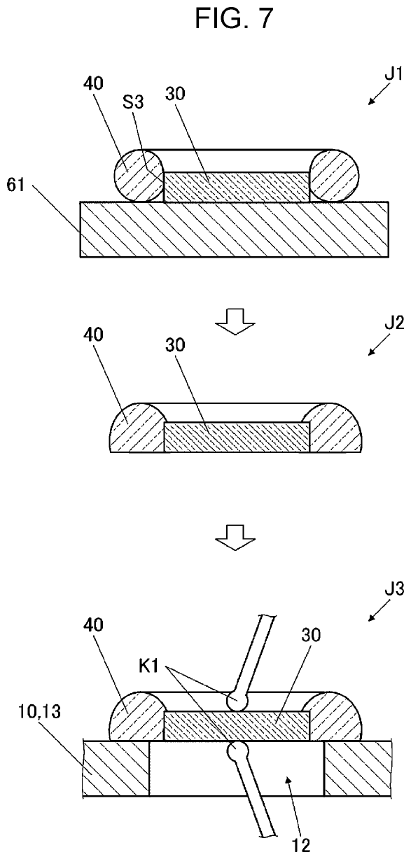

FIG. 7 is an explanatory diagram illustrating an example of how the light-transmitting member is joined in Variation 4. In Variation 4, the light-transmitting member 30 may be joined to the wall 13 by a series of steps including a preliminary sintering step J1, a transfer step J2, and a main sintering step J3. In the preliminary sintering step J1, a substrate 61 made of a material (e.g., aluminum nitride) to which low-melting glass cannot easily adhere is prepared. Then, the light-transmitting member 30 and the joint material 40 that has not melted are placed on the substrate 61. The joint material 40 that has not melted is in a powder state and is placed along the side surface S3 of the light-transmitting member 30 to surround the light-transmitting member 30. Also, in the preliminary sintering step J1, the joint material 40 is melted by heating. The joint material 40 is then hardened by cooling while adhering to the light-transmitting member 30. The heating in the preliminary sintering step J1 may be one that does not completely melt the joint material 40. In the transfer step J2, the light-transmitting member 30 and the joint material 40 are separated from the substrate 61 and transferred to the wall 13. The light-transmitting member 30 is aligned with the opening 12. In the main sintering step J3, the joint material 40 is melted by heating, with the aligned light-transmitting member 30 supported with a jig K1. By melting, the joint material 40 forms into a lump and exerts a high surface tension. Thus, in such a way as to reduce the surface area, the joint material 40 comes into surface-contact with the wall 13 while tightening the light-transmitting member 30 from therearound. By appropriately adjusting the amount of the joint material 40, the joint material 40 partially comes into contact with the second surface S2 of the light-transmitting member 30. Then, by being cooled, the joint material 40 hardens and can join the light-transmitting member 30, which is smaller than the opening 12, to the wall 13.

### (Variation 5)

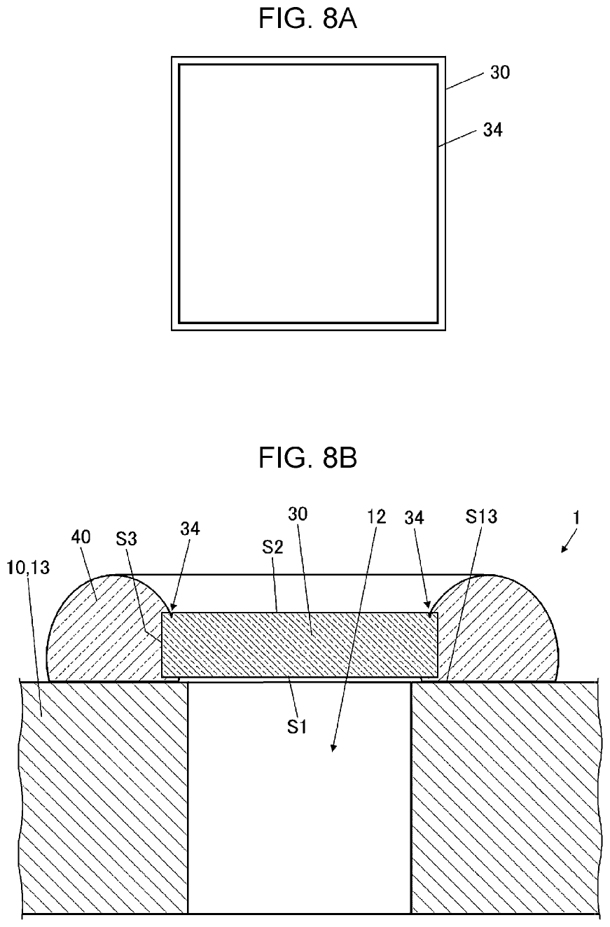

FIG. 8A is a front view illustrating the light-transmitting member of the optical component mounting package according to Variation 5. FIG. 8B is a cross-sectional view illustrating the vicinity of the opening of the optical component mounting package according to Variation 5. As in Variation 5, the light-transmitting member 30 may include a groove 34 surrounding the opening 12 in plan view and disposed in a region of the second surface S2 overlapping the wall 13 in plan view. The joint material 40 may be disposed on the second surface S2 without extending beyond the groove 34. The groove 34 can block the flow of the joint material 40 and reduce spreading of the joint material 40 toward the center of the second surface S2. The effective region of the light-transmitting member 30 can thus be easily secured.

The groove 34 may extend along the entire edge of the second surface S2, or may be disposed only in some region along the edge of the second surface S2.

### (Variation 6)

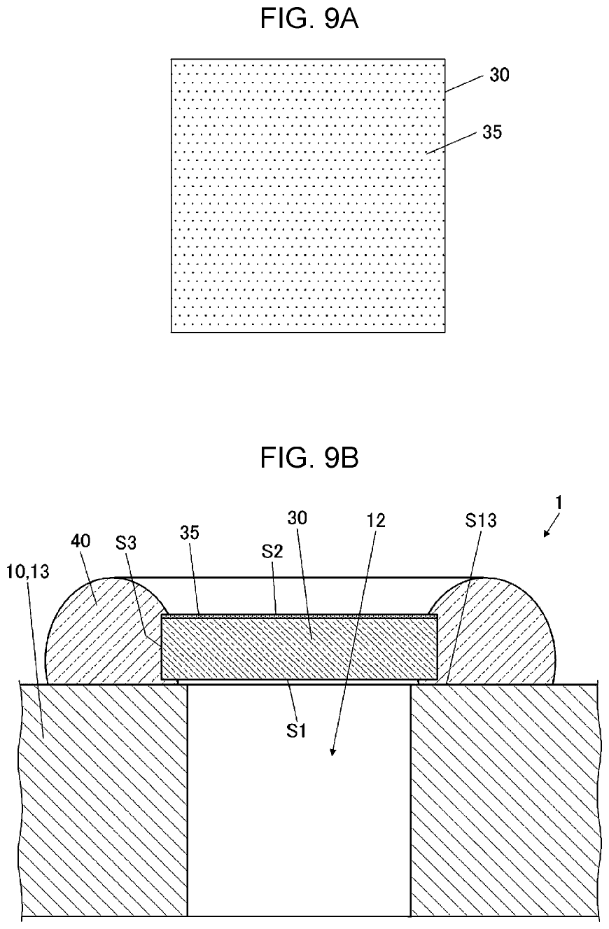

FIG. 9A is a front view illustrating the light-transmitting member of the optical component mounting package according to Variation 6. FIG. 9B is a cross-sectional view illustrating the vicinity of the opening of the optical component mounting package according to Variation 6. As in Variation 6, the light-transmitting member 30 may have thereon a non-oxide film 35 extending over the second surface S2. The non-oxide film 35 lowers the affinity of the joint material 40, and can reduce spreading of the joint material 40 over a wide range of the second surface S2. The effective region of the light-transmitting member 30 can thus be easily secured.

The non-oxide film 35 may extend over the entire area of the second surface S2 as illustrated in FIG. 9A, or may be disposed only in part of the second surface S2, such as in the vicinity of the edge of the second surface S2. The non-oxide film 35 of magnesium fluoride (MgF₂) or the like can be used. The non-oxide film 35 may also serve as a film having an optical effect, such as anti-reflection (AR) coating effect.

### (Variation 7)

Variation 7 is an example in which lead (Pb)-free low-melting glass is used as the joint material 40. Pb-free means that the lead content is equal to or less than 0.1 wt % (defined by the restriction of the use of certain hazardous substances in electrical and electronic equipment (RoHS)). Examples of the Pb-free low-melting glass that can be used include borosilicate glass, barium borosilicate glass, zinc borate glass, barium borate glass, high silicate glass, aluminophosphate glass, phosphate glass, zinc phosphate glass, alkali glass, bismuth silicate glass, bismuth borosilicate glass, and bismuth zinc borate glass. Using the Pb-free low-melting glass lowers affinity between the joint material 40 and the light-transmitting member 30, and can reduce spreading of the joint material 40 over a wide range of the second surface S2. The effective region of the light-transmitting member 30 can thus be easily secured.

### (Variations 8 and 9)

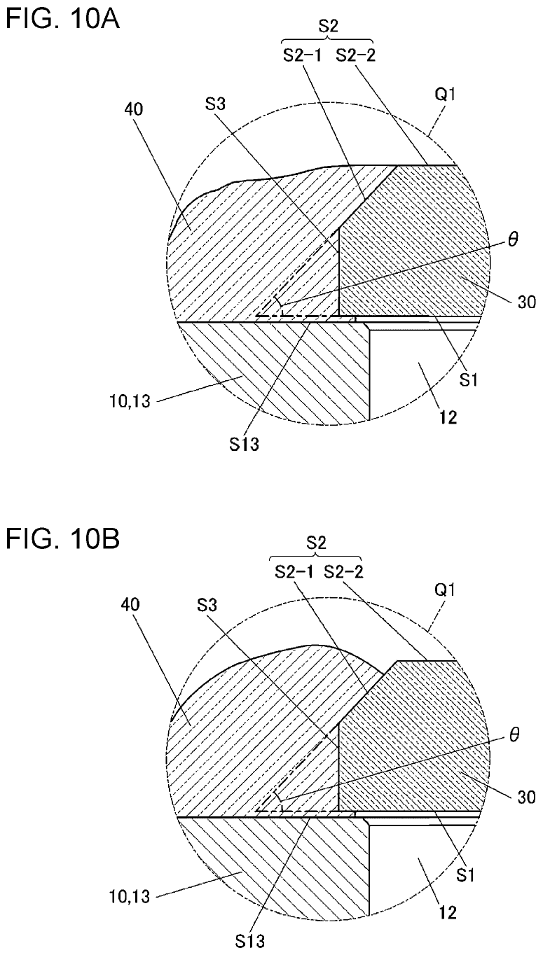

FIG. 10A is a cross-sectional view illustrating the vicinity of the opening of the optical component mounting package according to Variation 8. FIG. 10B is a cross-sectional view illustrating the vicinity of the opening of the optical component mounting package according to Variation 9. As illustrated in FIG. 10A and FIG. 10B, the second surface S2 may include a first portion S2-1 connected to the side surface S3, and a second portion S2-2 closer to the center than the first portion S2-1 is. In the cross-section perpendicular to the first surface S1, the first portion S2-1 may be inclined toward the center of the second surface S2 with increasing distance from the first surface S1 toward the second surface S2. In the cross-section described above, the angle of inclination of the first portion S2-1 (i.e., acute angle θ formed by the extension of the first surface S1 and the extension of the first portion S2-1) may be smaller than 60 degrees, or may be smaller than 45 degrees.

In the cross-section described above, the joint material 40 may be in contact with the entire first portion S2-1 (FIG. 10A), or may be in contact with part of the first portion S2-1 (FIG. 10B). This configuration also enables an anchoring action of the side surface S3 on the joint material 40, and can ensure firm joint between the light-transmitting member 30 and the wall 13. The strength and durability of the light-transmitting part of the optical component mounting package 1 can thus be improved.

As illustrated in FIG. 10B, the joint material 40 may protrude above the second surface S2 of the light-transmitting member 30 in the thickness direction of the joint material 40 (in the direction perpendicular to the first surface S1). The protruding portion of the joint material 40 can protect the light-transmitting member 30 from external obstacles. This can further improve the strength of the light-transmitting part of the optical component mounting package 1.

### <Optical Apparatus>

In the present embodiment, as illustrated in FIG. 1, the optical apparatus 100 includes the optical component mounting package 1 and the optical component 50 mounted in the optical component mounting package 1. The optical component 50 is a light-emitting device, such as a light-emitting diode or a laser diode, a light-receiving device, such as a photodiode, or an optical device, such as a lens, a mirror, or a diffraction grating. Multiple, and multiple types of, optical components 50 may be mounted on the mount 11. The optical apparatus 100 may further include an electronic component, and the electronic component may be mounted on the mount 11 in addition to the optical component 50. The optical component 50 transmits and receives light to and from the outside of the optical apparatus 100 through the opening 12 and the light-transmitting member 30.

In the present embodiment, the optical apparatus 100 can improve the strength of the light-transmitting part through the action of optical component mounting package 1 described above.

The optical component mounting package 1 and the optical apparatus 100 of the present embodiment have been described. The optical component mounting package and the optical apparatus of the present disclosure are not limited to the embodiments described above. For example, the opening 12 may be provided in the lid 20, not in the base body 10. In this case, a part of the lid 20 is a wall including the opening 12. The optical component mounting package may include a plurality of openings and a plurality of light-transmitting members. The light-transmitting member may be joined to the inner surface of the wall (i.e., surface closer to the mount). In the description above, some specific structures included in a cross-section perpendicular to the first surface S1 have been described with reference to the cross-section. However, the specific structures do not need to appear only in one cross-section perpendicular to the first surface S1, but may appear in all cross-sections perpendicular to the first surface S1 and passing through the light-transmitting member 30 and the opening 12, or may appear in all the cross-sections except those in a certain range. The wider the range that includes the specific structures, the greater the effect of the specific structures.

### INDUSTRIAL APPLICABILITY

The present disclosure can be used in optical component mounting packages and optical apparatuses.

### REFERENCE SIGNS

1 optical component mounting package
10 base body
11 mount
12 opening
13 wall
S13 third surface
15 accommodating portion
20 lid
30 light-transmitting member
34 groove
35 non-oxide film
40 joint material
42 bubble
S1 first surface
S2 second surface
S3 side surface
E1 inner peripheral edge of joint material
E2 edge of opening
D1, D2 thickness
T11, T12, T21, T22 length
H1 first range
H2 second range

1. An optical component mounting package comprising:
a mount on which an optical component is to be mounted;
a wall comprising an opening;
a light-transmitting member configured to cover the opening; and
a joint material configured to join the light-transmitting member to the wall,
wherein the light-transmitting member comprises a first surface facing the opening or disposed inside the opening, a second surface disposed opposite the first surface, and a side sur-face disposed between the first surface and the second surface; and
the joint material is a low-melting glass and is in contact with the wall, the side sur-face, and the second surface.

2. The optical component mounting package according to claim 1, wherein a thickness of the joint material is greater than a thickness of the light-transmitting member.

3. The optical component mounting package according to claim 1, wherein the joint material protrudes above the second surface.

4. The optical component mounting package according to claim 1, wherein in a cross-section perpendicular to the first surface, a contour of the joint material comprises an outward curve.

5. The optical component mounting package according to claim 1, wherein as viewed in a direction perpendicular to the first surface, the joint material has an annular shape along an edge of the light-transmitting member.

6. The optical component mounting package according to claim 1, wherein in a cross-section perpendicular to the first surface, a length of a contact between the joint material and the wall is greater than a length of a contact between the joint material and the side surface.

7. The optical component mounting package according to claim 1, wherein the light-transmitting member is joined to an outer surface of the wall.

8. The optical component mounting package according to claim 1, wherein as viewed through in a direction perpendicular to the first surface, an entire contour of the light-transmitting member is disposed inside an edge of the opening.

9. The optical component mounting package according to claim 1, wherein the joint material is further in contact with the first surface.

10. The optical component mounting package according to claim 1, wherein the wall comprises a third surface surrounding the opening and facing the first surface; and
in a space between the first surface and the third surface, the joint material is dis-posed in a first range farther from the opening and a gap is disposed in a second range closer to the opening.

11. The optical component mounting package according to claim 9, where-in in a cross-section perpendicular to the first surface, a length of a contact between the joint material and the first surface is greater than a length of a contact between the joint material and the second surface.

12. The optical component mounting package according to claim 1, wherein as viewed through in a direction perpendicular to the first surface, an inner peripheral edge of the joint material overlaps an edge of the opening, or is disposed outside the edge.

13. The optical component mounting package according to claim 1, wherein the light-transmitting member comprises a groove surrounding the opening in plan view and disposed in a region of the second surface overlapping the wall in plan view.

14. The optical component mounting package according to claim 1, wherein the joint material is a lead-free low-melting glass.

15. The optical component mounting package according to claim 1, wherein the light-transmitting member has thereon a non-oxide film extending over the second surface.

16. The optical component mounting package according to claim 1, wherein in a cross-section perpendicular to the first surface, the side surface has a convex shape or a concave shape.

17. The optical component mounting package according to claim 1, wherein the second surface comprises a first portion connected to the side surface; and
in a cross-section perpendicular to the first surface, the first portion is inclined to-ward a center of the second surface with increasing distance from the first surface toward the second surface.

18. The optical component mounting package according to claim 1, wherein the wall is made of ceramic.

19. The optical component mounting package according to claim 1, wherein the joint material contains bubbles in a corner between the side surface and the wall.

20. An optical apparatus comprising:
the optical component mounting package according to claim 1; and
an optical component mounted in the optical component mounting package.
